(19) United States
(12) Patent Application Publication
(10) Pub. No.: US 2012/0009791 A1
(43) Pub. Date: Jan. 12, 2012

(54) PATTERN FORMATION METHOD

(76) Inventors: Yingkang ZHANG, Kanagawa-ken (JP); Masafumi Asano, Kanagawa-ken (JP); Takeshi Koshiba, Mie-ken (JP)

(21) Appl. No.: 13/175,349

(22) Filed: Jul. 1, 2011

(30) Foreign Application Priority Data
Jul. 8, 2010 (JP) 2010-155750

(51) Int. Cl. H01L 21/311; B29C 35/08

(52) U.S. Cl. 438/694; 264/402; 257/E21.249

(57) ABSTRACT

According to one embodiment, a pattern formation method is disclosed. The method can include filling an imprint material between a first protrusion-depression pattern of a first pattern transfer layer formed on a first replica substrate and a second pattern transfer layer being transparent to energy radiation and formed on a second replica substrate transparent to the energy radiation. The method can include curing the imprint material by irradiating the imprint material with the energy radiation from an opposite surface side of the second replica substrate. The method can include releasing the first protrusion-depression pattern from the imprint material. The method can include forming a second protrusion-depression pattern in the second pattern transfer layer by processing the second pattern transfer layer using the imprint material as a mask.

### CROSS-REFERENCE TO RELATED APPLICATIONS

This application is based upon and claims the benefit of priority from Japanese Patent Application No. 2010-155750, filed on Jul. 8, 2010; the entire contents of which are incorporated herein by reference.

### FIELD

Embodiments described herein relate generally to a pattern formation method.

### BACKGROUND

In the imprint method, the protrusion-depression pattern of a template is brought into contact with an imprint material. In this state, the imprint material is cured. Subsequently, the template is released from the cured imprint material. When the imprint method is used particularly for pattern formation of a semiconductor device, low cost and mass productivity are required.

### BRIEF DESCRIPTION OF THE DRAWINGS

FIGS. 1A to 1D are schematic views showing a pattern formation method of an embodiment;

FIGS. 2A to 2C are schematic sectional views showing a method for manufacturing a master template;

FIGS. 3A to 3D are schematic sectional views showing a method for manufacturing a first replica template;

FIGS. 4A to 4D are schematic sectional views showing a method for manufacturing a second replica template;

FIGS. 5A and 5B are schematic sectional views showing another method for manufacturing the second replica template;

FIGS. 6A to 6C are schematic sectional views showing a pattern transfer method using the second replica template;

FIGS. 7A to 7C are schematic sectional views showing another method for manufacturing the first replica template; and

FIGS. 8A to 8C are schematic sectional views showing another method for manufacturing the first replica template.

### DETAILED DESCRIPTION

According to one embodiment, a pattern formation method is disclosed. The method can include filling an imprint material between a first protrusion-depression pattern of a first pattern transfer layer formed on a first replica substrate and a second pattern transfer layer being transparent to energy radiation and formed on a second replica substrate transparent to the energy radiation. The method can include curing the imprint material by irradiating the imprint material with the energy radiation from an opposite surface side of the second replica substrate. The method can include releasing the first protrusion-depression pattern from the imprint material. The method can include forming a second protrusion-depression pattern in the second pattern transfer layer by processing the second pattern transfer layer using the imprint material as a mask.

Various embodiments will be described hereinafter with reference to the accompanying drawings. In the drawings, like components are labeled with like reference numerals.

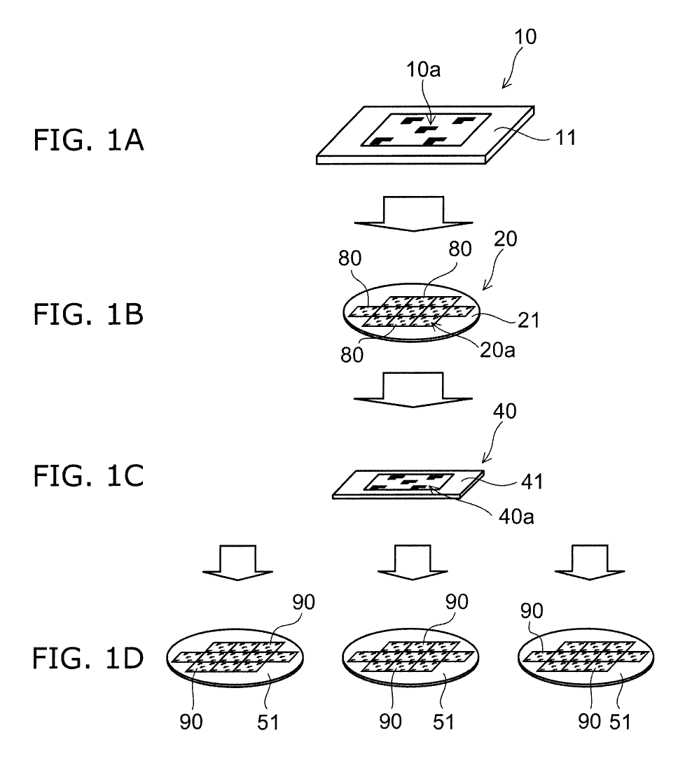

FIGS. 1A to 1D are schematic views showing a pattern formation method of an embodiment.

The pattern formation method of the embodiment includes the process of manufacturing a first replica template 20 using a master template 10, the process of manufacturing a second replica template 40 using the first replica template 20, and the process of transferring a second protrusion-depression pattern 40a formed in the second replica template 40 to a processing target layer of a subject substrate 51.

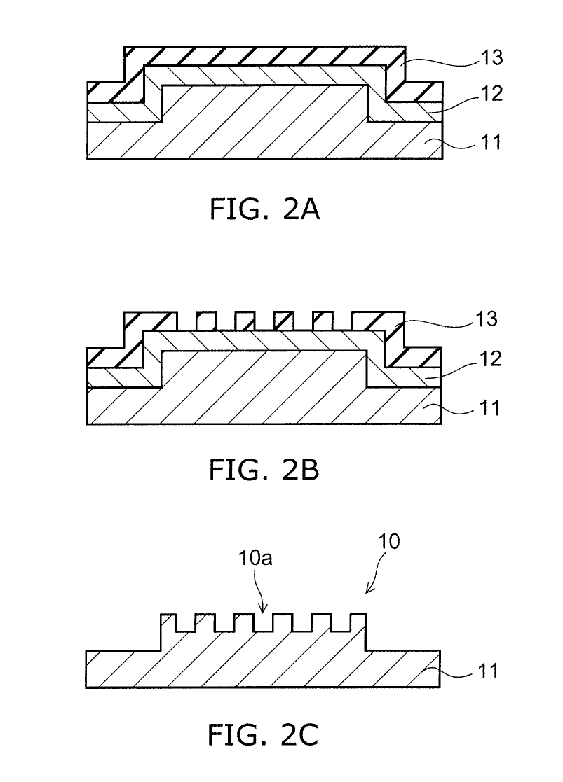

FIGS. 2A to 2C are schematic sectional views showing a method for manufacturing a master template 10.

First, as shown in FIG. 2A, a hard mask layer 12 is formed on the surface of a master substrate 11. The master substrate 11 is e.g. a quartz substrate. The material of the hard mask layer 12 can be e.g. chromium, tantalum, or molybdenum silicide. The thickness of the hard mask layer 12 is e.g. several to several ten nm.

A resist layer 13 is formed on the hard mask layer 12. The resist layer 13 has a property such that the portion irradiated with e.g. an electron beam or laser beam becomes soluble or insoluble in developer liquid.

On the resist layer 13, a desired pattern is written by an electron beam or laser beam. Subsequently, the resist layer 13 is selectively etched with developer liquid. Accordingly, as shown in FIG. 2B, openings are selectively formed in the resist layer 13. Thus, the resist layer 13 is patterned.

Then, using the patterned resist layer 13 as a mask, the hard mask layer 12 is etched, and furthermore the surface of the master substrate 11 is etched. Subsequently, the remaining resist layer 13 and hard mask layer 12 are removed.

Thus, as shown in FIG. 2C, a master template 10 is obtained. In the master template 10, a protrusion-depression pattern 10a is formed at the surface of the master substrate 11. The master substrate 11 has a mesa structure in which the central portion is projected relative to the outer peripheral portion. The protrusion-depression pattern 10a is formed at the surface of the projected portion. Thus, at the time of pattern transfer, contact in unwanted areas between the template and the pattern transfer target can be avoided.

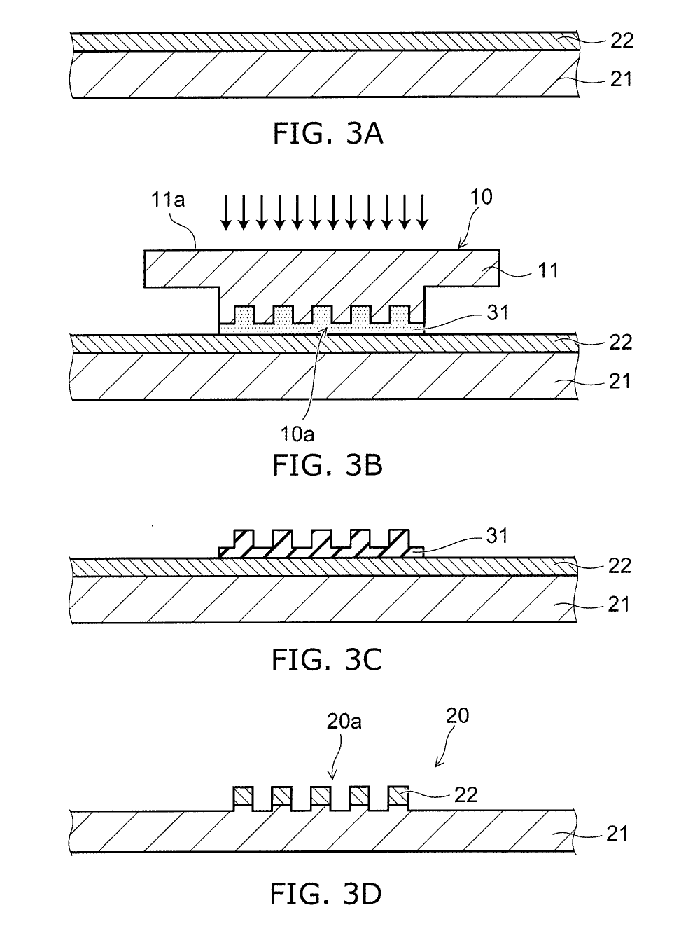

Next, FIGS. 3A to 3D are schematic sectional views showing a method for manufacturing a first replica template 20.

First, as shown in FIG. 3A, a hard mask layer 22 is formed as a first pattern transfer layer on a first replica substrate 21. The first replica substrate 21 is e.g. a silicon wafer. Here, the first replica substrate 21 can be a semiconductor wafer other than silicon. Alternatively, a glass wafer can also be used.

The material of the hard mask layer 22 can be e.g. chromium, tantalum, or molybdenum silicide. The thickness of the hard mask layer 22 is e.g. several to several ten nm. Here, the first pattern transfer layer is not limited to the monolayer structure of the hard mask layer 22, but a multilayer film can also be used.

Next, as shown in FIG. 3B, a first imprint material 31 is filled between the hard mask layer 22 and the protrusion-depression pattern 10a of the master template 10.

Specifically, first, the first imprint material 31 in liquid form is supplied onto the surface of the hard mask layer 22. The first imprint material 31 is an ultraviolet curable resin such as acrylate or methacrylate monomer. To improve releasability between the first imprint material 31 and the master template 10, a releasing material layer may be formed on the surface of the first imprint material 31.

Then, the protrusion-depression pattern 10a of the master template 10 is brought into contact with and pressed against the first imprint material 31. Thus, by capillarity, the first imprint material 31 is filled in the depressions (grooves) of the protrusion-depression pattern 10a.

In this state, the first imprint material 31 is irradiated with first energy radiation such as ultraviolet radiation. As indicated by thick arrows in FIG. 3B, the ultraviolet radiation is applied toward the first imprint material 31 from the opposite surface 11a side of the master substrate 11, the side being opposite to the surface with the protrusion-depression pattern 10a formed therein. The master substrate 11 is made of e.g. quartz, which is transparent to ultraviolet radiation. Hence, the master substrate 11 does not block transmission of ultraviolet radiation. Upon ultraviolet irradiation, the first imprint material 31 is cured.

After the first imprint material 31 is cured, the master template 10 is moved upward and released from the first imprint material 31. Thus, as shown in FIG. 3C, the first imprint material 31 patterned into a protrusion-depression configuration is formed on the hard mask layer 22. The protrusion-depression pattern of the first imprint material 31 is an inverted pattern of the protrusion-depression pattern 10a of the master template 10.

Next, using the patterned first imprint material 31 as a mask, by the reactive ion etching (RIE) method, for instance, the hard mask layer 22 is processed, and furthermore the surface of the first replica substrate 21 is processed. Subsequently, the remaining first imprint material 31 is removed. Thus, as shown in FIG. 3D, a first replica template 20 with a first protrusion-depression pattern 20a formed thereon is obtained. The first protrusion-depression pattern 20a is an inverted pattern of the protrusion-depression pattern 10a of the master template 10.

For the first replica substrate 21, a silicon wafer is used. Hence, the embodiment can use existing processing techniques and apparatuses such as for RIE, which are often used for pattern formation of semiconductor devices. Thus, a template having a high-accuracy protrusion-depression pattern with reduced variation in pattern dimension can be easily manufactured at low cost.

Furthermore, the first replica substrate 21 is a silicon wafer having a larger planar size than the master template 10. For a plurality of areas 80 (FIG. 1B) on the silicon wafer, pattern transfer using the aforementioned master template 10 is performed a plurality of times by the so-called step-and-repeat process.

After the protrusion-depression pattern of the first imprint material 31 is formed in the plurality of areas 80, using the first imprint material 31 as a mask, etching of the hard mask layer 22 and the silicon wafer (first replica substrate 21) is performed simultaneously on the plurality of areas 80. Thus, a first replica template 20 is obtained. In the first replica template 20, a plurality of first protrusion-depression patterns 20a are formed in the plurality of areas 80 on the silicon wafer.

By repeating the above processes, a plurality of first replica templates 20 can be obtained.

Here, the embodiment is not limited to the imprint method. For instance, by the deep ultraviolet (DUV) exposure method or the electron beam lithography method, the first protrusion-depression pattern 20a can be formed to fabricate a first replica template 20.

The hard mask layer 22 with the first protrusion-depression pattern 20a formed therein is a metal layer or metal silicide layer having conductivity. This can prevent charge-up at the time of visual inspection of the first protrusion-depression pattern 20a using an electron microscope.

The first protrusion-depression pattern 20a of the first replica template 20 is further transferred to a second replica template 40. At this time, one of the plurality of first protrusion-depression patterns 20a formed in the plurality of areas 80 is selected and used to perform pattern transfer to the second replica template 40. That is, a first protrusion-depression pattern 20a with high dimensional accuracy and no shape defect can be selected. Thus, a second protrusion-depression pattern 40a formed in the second replica template 40 can also be realized with high dimensional accuracy and no shape defect.

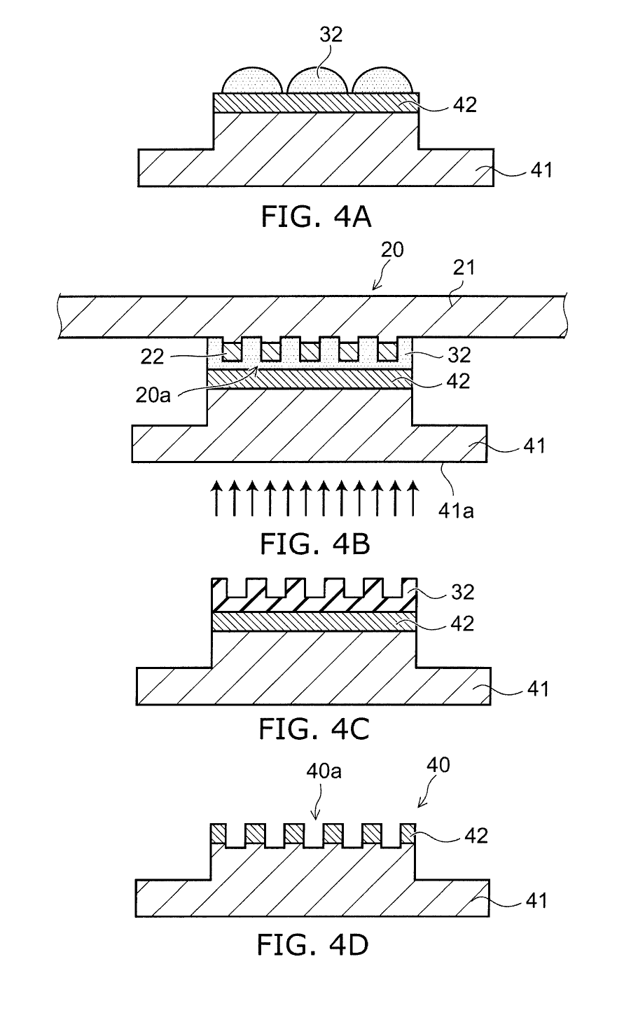

FIGS. 4A to 4D are schematic sectional views showing a method for manufacturing a second replica template 40.

First, as shown in FIG. 4A, a hard mask layer 42 is formed as a second pattern transfer layer on a second replica substrate 41. The second replica substrate 41 has a smaller planar size than the first replica substrate 21. The second replica substrate 41 is transparent to all or part of the wavelength region of second energy radiation such as ultraviolet radiation. For instance, the second replica substrate 41 can be a quartz substrate.

Like the master template 10, the second replica substrate 41 has a mesa structure. The hard mask layer 42 is formed on the surface of the projected portion of the mesa structure. The hard mask layer 42 is also transparent to all or part of the wavelength region of ultraviolet radiation. The material of the hard mask layer 42 can be e.g. chromium, tantalum, or molybdenum silicide. The thickness of the hard mask layer 42 is e.g. several to several ten nm. A layer for improving adhesiveness to the second imprint material 32 described below may be formed on the surface of the hard mask layer 42.

A second imprint material 32 in liquid form is supplied onto the hard mask layer 42. The second imprint material 32 is an ultraviolet curable resin such as acrylate or methacrylate monomer.

Next, the first protrusion-depression pattern 20a of the first replica template 20 is brought into contact with and pressed against the second imprint material 32. The first protrusion-depression pattern 20a used here is one selected from the plurality as described above.

As shown in FIG. 4B, the second imprint material 32 is filled between the hard mask layer 42 on the second replica substrate 41 and the first protrusion-depression pattern 20a of the first replica template 20. By capillarity, the second imprint material 32 is filled in the depressions (grooves) of the first protrusion-depression pattern 20a.

In this state, the second imprint material 32 is irradiated with second energy radiation such as ultraviolet radiation. In the normal imprint method, ultraviolet radiation is applied toward the imprint material from the rear surface side of the template including the protrusion-depression pattern. However, the first replica substrate 21 serving as a template in this case is a silicon wafer, which is not transparent to ultraviolet radiation.

Thus, as indicated by thick arrows in FIG. 4B, ultraviolet radiation is applied toward the second imprint material 32 from the opposite surface 41a side of the second replica substrate 41, the side being opposite to the surface with the hard mask layer 42 formed thereon. The second replica substrate 41 and the hard mask layer 42 are transparent to ultraviolet radiation, and hence do not block transmission of ultraviolet radiation. Upon ultraviolet irradiation, the second imprint material 32 is cured.

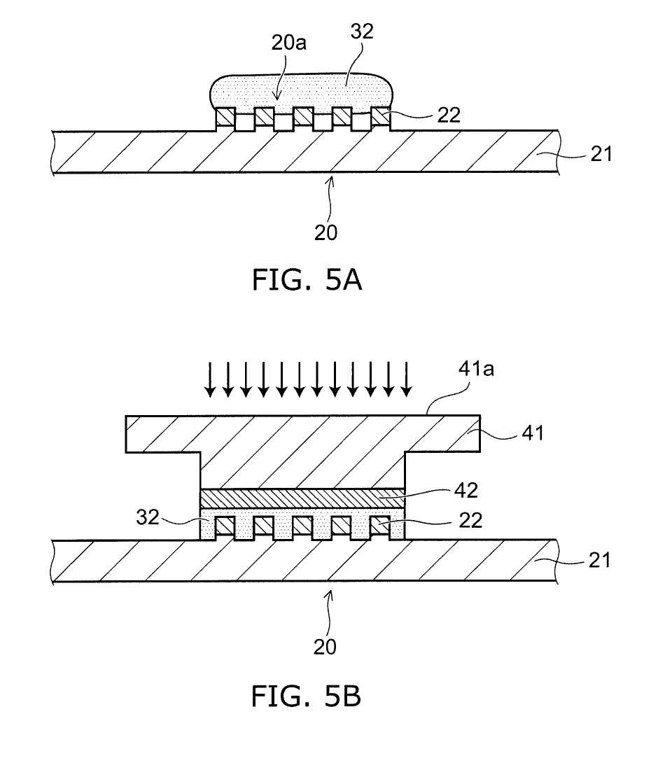

Alternatively, as shown in FIG. 5A, a second imprint material 32 in liquid form is supplied onto the first protrusion-depression pattern 20a of the first replica template 20. Subsequently, as shown in FIG. 5B, the hard mask layer 42 formed on the second replica substrate 41 may be brought into contact with and pressed against the second imprint material 32.

In this case, the second imprint material 32 is previously supplied onto the first protrusion-depression pattern 20a. While the second replica substrate 41 is set above the first replica template 20 and moved toward the first replica template 20, the second imprint material 32 can be caused to penetrate into the depressions of the first protrusion-depression pattern 20a. This can reduce the time to press the first replica template 20 and the hard mask layer 42 against the second imprint material 32.

Also in this case, as indicated by thick arrows in FIG. 5B, ultraviolet radiation is applied toward the second imprint material 32 from the opposite surface 41a side of the second replica substrate 41, the side being opposite to the surface with the hard mask layer 42 formed thereon.

After the second imprint material 32 is cured, the first replica template 20 is released from the second imprint material 32. Thus, as shown in FIG. 4C, the second imprint material 32 patterned into a protrusion-depression configuration is formed on the hard mask layer 42. The protrusion-depression pattern of the second imprint material 32 is an inverted pattern of the first protrusion-depression pattern 20a of the first replica template 20.

Next, using the patterned second imprint material 32 as a mask, by the RIE method, for instance, the hard mask layer 42 is processed, and furthermore the surface of the second replica substrate 41 is processed. Subsequently, the remaining second imprint material 32 is removed. Thus, as shown in FIG. 4D, a second replica template 40 with a second protrusion-depression pattern 40a formed thereon is obtained. The second protrusion-depression pattern 40a is an inverted pattern of the first protrusion-depression pattern 20a of the first replica template 20.

By repeating the above processes, a plurality of second replica templates 40 can be obtained.

The hard mask layer 42 with the second protrusion-depression pattern 40a formed therein is a metal layer or metal silicide layer having conductivity. This can prevent charge-up at the time of visual inspection of the second protrusion-depression pattern 40a using an electron microscope.

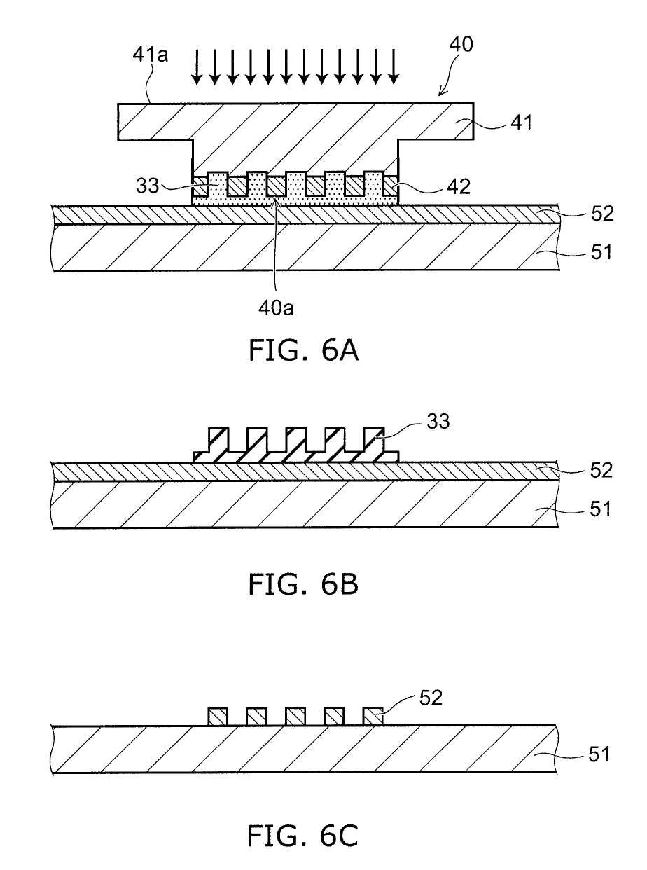

As shown in FIGS. 6A to 6C, this second replica template 40 is used to perform processing on a final pattern formation target.

The pattern formation target is a subject substrate 51 or a processing target layer 52 formed on the subject substrate 51. The subject substrate 51 is a semiconductor wafer such as a silicon wafer. The processing target layer 52 is e.g. an insulating layer, metal layer, or semiconductor layer.

As shown in FIG. 6A, an imprint material 33 is filled between the processing target layer 52 and the second protrusion-depression pattern 40a of the second replica template 40.

Specifically, first, the imprint material 33 in liquid form is supplied onto the surface of the processing target layer 52. The imprint material 33 is an ultraviolet curable resin such as acrylate or methacrylate monomer. To improve releasability between the imprint material 33 and the second replica template 40, a releasing material layer may be formed on the surface of the imprint material 33.

Then, the second protrusion-depression pattern 40a of the second replica template 40 is brought into contact with and pressed against the imprint material 33. Thus, by capillarity, the imprint material 33 is filled in the depressions (grooves) of the second protrusion-depression pattern 40a.

In this state, the imprint material 33 is irradiated with energy radiation such as ultraviolet radiation. As indicated by thick arrows in FIG. 6A, the ultraviolet radiation is applied toward the imprint material 33 from the opposite surface 41a side of the second replica substrate 41, the side being opposite to the surface with the second protrusion-depression pattern 40a formed therein. The second replica substrate 41, and the hard mask layer 42 with the second protrusion-depression pattern 40a formed therein, are transparent to ultraviolet radiation, and hence do not block transmission of ultraviolet radiation. Upon ultraviolet irradiation, the imprint material 33 is cured.

After the imprint material 33 is cured, the second replica template 40 is moved upward and released from the imprint material 33. Thus, as shown in FIG. 6B, the imprint material 33 patterned into a protrusion-depression configuration is formed on the processing target layer 52. The protrusion-depression pattern of the imprint material 33 is an inverted pattern of the second protrusion-depression pattern 40a of the second replica template 40.

Next, using the patterned imprint material 33 as a mask, by the RIE method, for instance, the processing target layer 52 is processed. Subsequently, the remaining imprint material 33 is removed. Thus, as shown in FIG. 6C, the processing target layer 52 is patterned into a protrusion-depression configuration. This protrusion-depression pattern is an inverted pattern of the second protrusion-depression pattern 40a of the second replica template 40.

The subject substrate 51 is a semiconductor wafer having a larger planar size than the second replica template 40. For a plurality of chip areas 90 (FIG. 1D) on the semiconductor wafer, pattern transfer using the aforementioned second replica template 40 is performed a plurality of times by the so-called step-and-repeat process.

After the protrusion-depression pattern of the imprint material 33 is formed in the plurality of chip areas 90, using the imprint material 33 as a mask, etching of the processing target layer 52 is performed simultaneously on the plurality of chip areas 90. Thus, the protrusion-depression pattern of the processing target layer 52 is formed in each chip area 90 on the semiconductor wafer.

By repeating the above processes, pattern formation can be performed on a plurality of subject substrates 51.

If pattern transfer is repeated using the same template, the pattern of the template is worn away. This results in increasing transfer defects of the pattern. Thus, in order to reduce transfer defects and improve mass productivity, it is desirable to fabricate a plurality of templates.

However, in general, electron beam lithography is slow in throughput and requires a long time in fabricating the template. This causes cost increase of the template. Hence, it is desired to minimize the number of templates requiring electron beam lithography.

According to the embodiment, electron beam lithography is applied only to the master template 10. Then, from the master template 10 through the first replica template 20, a plurality of second replica templates 40 can be fabricated. Thus, a large number of replica templates are obtained in a short period of time. Because a large number of replica templates are obtained, the cost per replica template is reduced.

Furthermore, the protrusion-depression pattern 10a of the master template 10 is transferred to a plurality of areas 80 on the first replica substrate 21. Then, one of the first protrusion-depression patterns 20a formed in the plurality of areas 80 can be selected and transferred to the second replica template 40. As a result, the second protrusion-depression pattern 40a can be formed in the second replica template 40 with high accuracy and no defect. The pattern in the final product wafer obtained by transferring the second protrusion-depression pattern 40a can also be realized with high accuracy and reduced defects.

Furthermore, the first protrusion-depression pattern 20a in the first replica template 20 and the second protrusion-depression pattern 40a in the second replica template 40 are formed from not an imprint material made of a resin material, but from a hard mask layer harder than the resin material. Hence, the first protrusion-depression pattern 20a and the second protrusion-depression pattern 40a have high strength and durability, and are less prone to transfer defects even when pattern transfer is repeated a plurality of times.

A resolution limit exists in electron beam lithography or light exposure. Hence, in fabricating the master template 10, the pattern size has a lower limit. In principle, a template having a pattern finer than the lower limit cannot be fabricated.

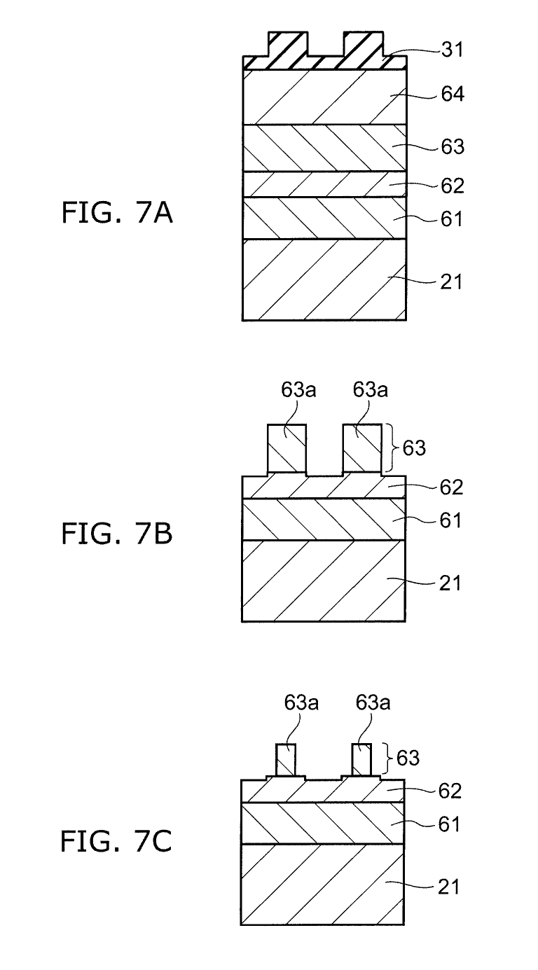

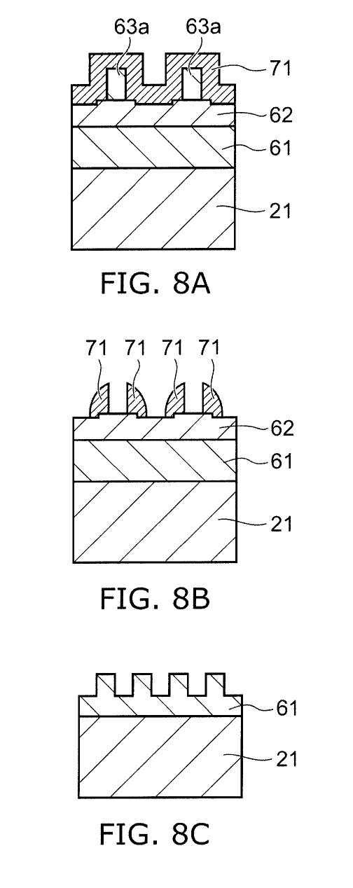

Thus, an embodiment described below with reference to FIGS. 7A to 8C proposes a method for producing a template having a pattern finer than the resolution limit of electron beam lithography or light exposure.

FIG. 7A corresponds to the state of FIG. 3C in the aforementioned embodiment.

More specifically, in the embodiment, a first pattern transfer layer having a multilayer structure including a first layer 61, a hard mask layer 62, a second layer 63, and a hard mask layer 64 is formed on the first replica substrate 21.

The first layer 61 is formed on the first replica substrate 21 such as a silicon wafer. The hard mask layer 62 is formed on the first layer 61. The second layer 63 is formed on the hard mask layer 62. The hard mask layer 64 is formed on the second layer 63. For instance, the first layer 61 and the second layer 63 are silicon oxide layers. The hard mask layers 62, 64 are silicon nitride layers.

As in the aforementioned embodiment, by the imprint method using a master template 10, a first imprint material 31 processed into a protrusion-depression configuration is formed on the hard mask layer 64.

Then, using the first imprint material 31 as a mask, the hard mask layer 64 is processed, and furthermore the second layer 63 is processed. Subsequently, the first imprint material 31 and the hard mask layer 64 are removed by such a method as ashing. Thus, as shown in FIG. 7B, a protrusion-depression pattern is formed in the second layer 63. The height of the protrusion 63a, or the depth of the depression, in this protrusion-depression pattern is several ten to hundred nm.

Next, by the wet etching method, for instance, the protrusions 63a are slimmed. Thus, as shown in FIG. 7C, the width of the protrusion 63a is reduced. The height of the protrusion 63a is also lowered. By this slimming process, the width of the protrusion 63a is reduced by approximately half. That is, the width of the slimmed protrusion 63a in FIG. 7C is approximately half the protrusion of the protrusion-depression pattern 10a of the master template 10.

Next, as shown in FIG. 8A, by the chemical vapor deposition (CVD) method, for instance, a sidewall layer 71 is formed on the hard mask layer 62 and on the protrusions 63a. The sidewall layer 71 is made of a material, such as silicon, different from that of the protrusion 63a. The sidewall layer 71 is formed also on the sidewall of the protrusion 63a. The sidewall layer 71 covers the upper surface and sidewall of the protrusion 63a, and the bottom surface of the depression between the adjacent protrusions 63a. The film thickness of the sidewall layer 71 is determined by the size of the first protrusion-depression pattern to be formed on the first replica substrate 21. For instance, the film thickness of the sidewall layer 71 is several to several ten nm, nearly equal to the width of the protrusion 63a.

Next, anisotropic etching such as the RIE method is performed on the sidewall layer 71. Thus, the sidewall layer 71 covering the upper surface of the protrusion 63a and the depression between the protrusions 63a is removed. The sidewall layer 71 formed on the sidewall of the protrusion 63a is left.

Next, by the wet etching method, for instance, the protrusion 63a sandwiched between the remaining portions of sidewall layer 71 is removed. The protrusion 63a and the sidewall layer 71 are different in material. The sidewall layer 71 is resistant to the etching liquid used at this time. Hence, as shown in FIG. 8B, the sidewall layer 71 is left. The repetition pitch of the protrusion-depression pattern formed from this sidewall layer 71 is approximately half the repetition pitch of the protrusion-depression pattern of the first imprint material 31 in FIG. 7A, i.e., the repetition pitch of the protrusion-depression pattern 10a of the master template 10.

Next, using the sidewall layer 71 as a mask, by the RIE method, for instance, the hard mask layer 62 is processed, and furthermore the first layer 61 is processed. Subsequently, the remaining sidewall layer 71 and hard mask layer 62 are removed. Thus, as shown in FIG. 8C, a protrusion-depression pattern is formed in the first layer 61. This protrusion-depression pattern of the first layer 61 corresponds to the first protrusion-depression pattern in the first replica template.

The protrusion-depression pattern of the first layer 61 is obtained by etching in which the sidewall layer 71 shown in FIG. 8B is used as a mask. Hence, the pitch of the protrusion-depression pattern of the first layer 61 is approximately half that of the protrusion-depression pattern 10a of the master template 10. That is, a first replica template having a finer pattern than the resolution limit of e.g. electron beam lithography can be fabricated.

For the first replica substrate 21, a semiconductor wafer is used. Hence, the process of forming the aforementioned multilayer film and sidewall layer 71 on the semiconductor wafer, and the process of processing them, can be performed by commonly-used semiconductor wafer processes with high accuracy and low cost.

Subsequently, as in the aforementioned embodiment, this first replica template is used to fabricate a second replica template 40. Furthermore, the second replica template 40 is used to perform pattern formation on a processing target. As a result, a fine protrusion-depression pattern is formed in the processing target. In this protrusion-depression pattern, the width of the protrusion, the width of the depression, or the repetition pitch of protrusions and depressions, is smaller than that of the protrusion-depression pattern 10a of the master template 10.

Here, the second replica template 40 thus fabricated may be used as a template to fabricate still another replica template (third replica template). In this case, for the substrate of the third replica template, a semiconductor wafer is used as in the aforementioned first replica substrate 21. Hence, by using existing wafer processing techniques and performing the process shown in FIGS. 7A to 8C, a replica template having an even finer protrusion-depression pattern can be obtained. The third replica template can be used to perform pattern formation on a product wafer. Thus, an even finer protrusion-depression pattern can be formed in the product wafer. Here, still another replica template having an even finer pattern may be fabricated from the third replica template.

The aforementioned pattern formation method is not limited to manufacturing of semiconductor devices, but is also applicable to pattern formation of e.g. optical components and disc media.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A pattern formation method comprising:
filling an imprint material between a first protrusion-depression pattern of a first pattern transfer layer formed on a first replica substrate and a second pattern transfer layer being transparent to energy radiation and formed on a second replica substrate transparent to the energy radiation;
curing the imprint material by irradiating the imprint material with the energy radiation from an opposite surface side of the second replica substrate, the side being opposite to a surface of the second replica substrate with the second pattern transfer layer formed on the surface;
after the curing the imprint material, releasing the first protrusion-depression pattern from the imprint material; and
after the releasing the first protrusion-depression pattern from the imprint material, forming a second protrusion-depression pattern in the second pattern transfer layer by processing the second pattern transfer layer using the imprint material as a mask.

2. The method according to claim 1, wherein
forming the first pattern transfer layer includes:
forming a first layer on the first replica substrate; and
forming a second layer on the first layer, and forming the first protrusion-depression pattern includes:
processing the second layer into a protrusion-depression configuration;
slimming a protrusion in the second layer processed into the protrusion-depression configuration;
forming a sidewall layer on a sidewall of the slimmed protrusion, the sidewall layer being different in material from the second layer;
removing the protrusion between the sidewall layers; and
processing the first layer into a protrusion-depression configuration using as a mask the sidewall layer left after removal of the protrusion.

3. The method according to claim 1, wherein
the first replica substrate is a semiconductor wafer, and
the first protrusion-depression pattern is formed in each of a plurality of areas on the semiconductor wafer.

4. The method according to claim 3, wherein one of a plurality of the first protrusion-depression patterns formed in the plurality of areas is selected and used to perform pattern transfer on the second pattern transfer layer.

5. The method according to claim 2, wherein
the first replica substrate is a semiconductor wafer, and
the first protrusion-depression pattern is formed in each of a plurality of areas on the semiconductor wafer.

6. The method according to claim 5, wherein one of a plurality of the first protrusion-depression patterns formed in the plurality of areas is selected and used to perform pattern transfer on the second pattern transfer layer.

7. The method according to claim 1, wherein the filling the imprint material between the second pattern transfer layer and the first protrusion-depression pattern includes:
supplying the imprint material onto the first protrusion-depression pattern; and
pressing the second pattern transfer layer against the imprint material on the first protrusion-depression pattern.

8. The method according to claim 1, wherein the filling the imprint material between the second pattern transfer layer and the first protrusion-depression pattern includes:
supplying the imprint material onto the second pattern transfer layer; and
pressing the first protrusion-depression pattern against the imprint material on the second pattern transfer layer.

9. The method according to claim 1, wherein
forming the first protrusion-depression pattern includes:
filling a first imprint material between a protrusion-depression pattern in a master template and the first pattern transfer layer, and curing the first imprint material to transfer an inverted pattern of the protrusion-depression pattern of the master template to the first imprint material;
releasing the master template from the cured first imprint material; and
after the releasing the master template from the first imprint material, processing the first pattern transfer layer using the pattern of the first imprint material as a mask.

10. The method according to claim 9, wherein
the first replica substrate is a semiconductor wafer, and the pattern of the first imprint material is formed in each of a plurality of areas on the semiconductor wafer, and
etching of the first pattern transfer layer using the pattern of the first imprint material as a mask is performed simultaneously on the plurality of areas.

11. The method according to claim 1, wherein the first pattern transfer layer is conductive.

12. The method according to claim 1, wherein the second pattern transfer layer is conductive.

13. The method according to claim 1, wherein the first pattern transfer layer is a hard mask layer harder than a resin material.

14. The method according to claim 1, wherein the second pattern transfer layer is a hard mask layer harder than a resin material.

15. The method according to claim 1, wherein the imprint material made of an ultraviolet curable resin is irradiated with ultraviolet radiation as the energy radiation.
